(19) United States
(12) Patent Application Publication
(10) Pub. No.: US 2020/0086453 A1
(43) Pub. Date: Mar. 19, 2020

(54) NON-CONTACT ROTARY UNION

(71) Applicant: Applied Materials, Inc., Santa Clara, CA (US)

(72) Inventor: Edward GOLUBOVSKY, San Jose, CA (US)

(21) Appl. No.: 16/543,160

(22) Filed: Aug. 16, 2019

Related U.S. Application Data
(60) Provisional application No. 62/731,409, filed on Sep. 14, 2018.

(51) Int. Cl. B24B 37/20; F16L 27/08; F16L 17/10; B24B 57/02; H01L 21/67; H01L 21/304; B24B 37/26

(52) U.S. Cl. CPC B24B 37/205; F16L 27/0828; F16L 27/082; F16L 27/0816; B24B 37/26; B24B 57/02; H01L 21/67051; H01L 21/304; F16L 17/10

(57) ABSTRACT

Embodiments described herein relate to rotary unions for use in wafer cleaning processes. The rotary union includes a process media and a supporting media that interact in a gap between a nozzle and rotary element. By regulating the supporting media pressure, a non-contact seal is created within the gap. The non-contact seal prevents or controls process media leakage in a rotary union while enabling delivery of the process media through a platen directly underneath of a wafer without the risk of additional contamination of the process media, reducing the defect to the wafer. Additionally, the non-contact seal precludes particle generation due to seal wear, caused for example in face seals, and does not leech out any additional foreign elements.

### CROSS-REFERENCE TO RELATED APPLICATIONS

This application claims priority to U.S. Provisional Patent Application No. 62/731,409, filed Sep. 14, 2018, which is herein incorporated by reference in its entirety.

### BACKGROUND

### Field

Embodiments described herein generally relate to devices and methods used to transfer fluids through parts that rotate relative to each other, and, more particularly, to rotary unions for use in wafer cleaning processes.

### Description of the Related Art

Chemical mechanical polishing (CMP) is one process commonly used in the manufacture of high-density integrated circuits to planarize or polish a layer of material deposited on a substrate. CMP is effectively employed by providing contact between a feature-containing side of the substrate and a polishing pad by moving the substrate relative to a polishing pad while in the presence of a polishing fluid. Applying the polishing fluid requires a fluid coupling device, such as a rotary union, that transfers a fluid medium from a stationary source into a rotating element.

Rotary unions typically include a stationary rotary element, which has an inlet port of receiving fluid medium. A non-rotating seal member is mounted within the rotary element. A rotating member, often referred to as a rotor, includes a rotating seal member and an outlet port for delivering fluid to a rotating component. A seal surface of the non-rotating seal member is biased into fluid-tight engagement with the seal surface of the rotating seal member, enabling a seal to be formed between the rotating and non-rotating components of the union. The seal permits transfer of fluid medium through the union without significant leakage between the non-rotating and rotating portions.

Conventional rotary unions for fluid medium delivery also typically use a face seal to prevent leakage. However, the face seal becomes worn over time during normal use, creating particles which may contaminate the fluid medium that is provided to downstream components, such as the polishing pad and substrate surface. Face seals used in conventional rotary unions may also become contaminated with foreign elements that leech out from the face seal material. These problems can contaminate the fluid delivered to the surface of the substrate during a CMP polishing process and thus cause damage to the surface of the substrate.

Accordingly, there is a need for a rotary union that enables delivery of a fluid medium without the risk of additional contamination to the fluid medium.

### SUMMARY

One or more embodiments described herein relate to rotary unions for use in wafer cleaning processes.

In one embodiment, a rotary union includes a rotary element rotationally coupled to a stationary element by a bearing, wherein a surface of the rotary element is spaced a distance from a first surface of the stationary element to form a first gap, and wherein the stationary element comprises: a nozzle region that has an external surface disposed at one end of the nozzle region; a first channel that extends through the nozzle region and the external surface of the nozzle region; and a second channel that is in fluid communication with a first plenum, wherein the first plenum is defined by one or more surfaces of the stationary element and one or more surfaces of the rotary element, and the first plenum is in fluid communication with the space formed within the first gap.

One or more embodiments described herein relate to methods for chemical mechanical polishing.

In one embodiment, a method for transferring one or more fluids between components of a rotary union includes delivering a process media from a first fluid source into a first channel at a first pressure, wherein the first channel extends into a stationary element of the rotary union, and the rotary union further comprises a first gap that is formed between the stationary element and a rotary element that is rotationally coupled to the stationary element; and delivering a supporting media from a second fluid source into a second channel at a second pressure, wherein the second channel extends into a plenum that is defined by one or more surfaces of the stationary element and one or more surfaces of the rotary element, wherein the plenum is fluidly coupled to the first gap at one end, and wherein the application of the supporting media inhibits the process media from entering the first gap.

One or more embodiments described herein relate to systems for chemical mechanical polishing.

In one embodiment, a system for transferring one or more fluids between components that are configured to rotate relative to each other includes a rotary union comprising: a rotary element rotationally coupled to a stationary element by a bearing, wherein a surface of the rotary element is spaced a distance from a first surface of the stationary element to form a first gap; wherein the stationary element comprises: a nozzle region that has an external surface disposed at one end of the nozzle region; a first channel that extends from a first fluid source external of the rotary union through the nozzle region and the external surface of the nozzle region; and a second channel that extends from a second fluid source external of the rotary union, wherein the second channel is in fluid communication with a first plenum, wherein the first plenum is defined by one or more surfaces of the stationary element and one or more surfaces of the rotary element, and the first plenum is in fluid communication with the space formed within the first gap; wherein the first fluid source is configured to deliver a process media at a first pressure; the second fluid source configured to deliver a supporting media at a second pressure; and the delivery of the supporting media inhibits the process media from entering the first gap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a side sectional view of a CMP system according to at least one embodiment in the present disclosure;

FIG. 2A is a perspective view of the rotary union in FIG. 1;

FIG. 2B is a bottom view of the rotary union in FIG. 1;

FIG. 2C is sectional view of the rotary union in FIG. 1;

FIG. 2D is another sectional view of the rotary union in FIG. 1; and

FIG. 2E is a close up sectional view of a portion of the rotary union in FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are set forth to provide a more thorough understanding of the embodiments of the present disclosure. However, it will be apparent to one of skill in the art that one or more of the embodiments of the present disclosure may be practiced without one or more of these specific details. In other instances, well-known features have not been described in order to avoid obscuring one or more of the embodiments of the present disclosure.

Embodiments described herein generally relate to rotary unions and, more particularly, to rotary unions for use in a semiconductor process that utilize one or more processing fluids, such as processing fluids used in a CMP process or a wafer cleaning process. The rotary union includes a plurality of stationary parts, or plurality of stationary elements, that include a nozzle and at least one rotating component. The rotary union acts to transfer a fluid from a stationary component to a rotating component. In some embodiments described herein, a process media and a supporting media are transferred from their stationary components to the rotating component. By regulating the supporting media pressure between the stationary and rotating components, a device that is able to transfer a fluid from a stationary component to a rotating component without leakage of the transferred fluid into unwanted regions of the rotary union or from undesirable regions of the rotary union is created, which will be described in detail below.

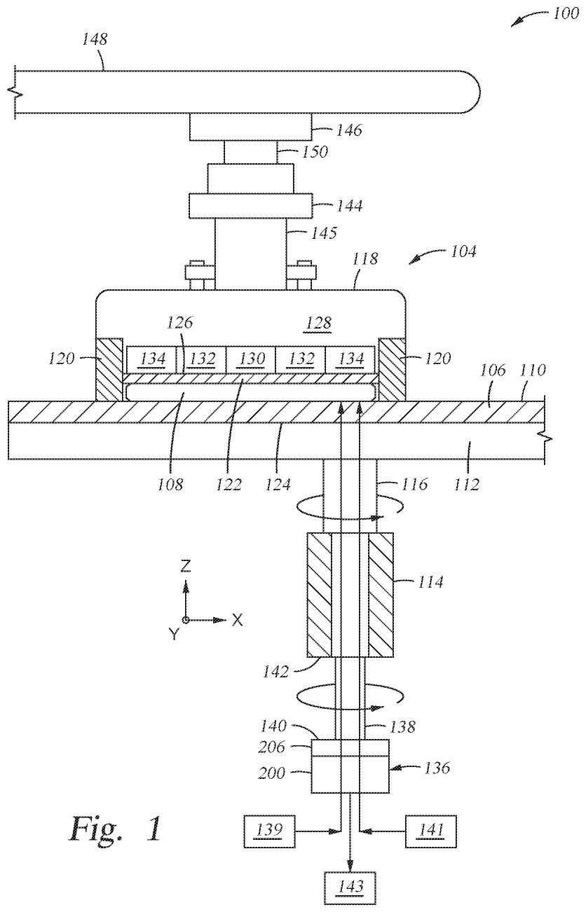

FIG. 1 is a side sectional view of a CMP system 100 according to at least one embodiment in the present disclosure. The CMP system 100 includes a polishing head 104 and a polishing pad 106. The polishing head 104 holds a substrate 108 in contact with a polishing surface 110 of the polishing pad 106. The polishing pad 106 is disposed on a platen 112. The platen 112 is coupled to a motor 114 by a platen shaft 116. The motor 114 rotates the platen 112, which also rotates the polishing surface 110 of the polishing pad 106, about an axis of the platen shaft 116 when the CMP system 100 is polishing the substrate 108.

The polishing head 104 includes a housing 118 circumscribed by retaining rings 120. A flexible membrane 122 is secured to the housing 118. The flexible membrane 122 includes an outer surface 124 to contact the substrate 108 and an inner surface 126 to face an interior 128 of the housing 118. A plurality of pressurizable chambers 130, 132, 134 are disposed in the housing 118. Each pressurizable chamber 130, 132, 134 contacts the inner surface 126 of the flexible membrane 122. The pressurizable chambers 130, 132, 134 are concentrically arranged around the center-line of the flexible membrane 122. The innermost pressurized chamber (pressurizable chamber 130) contacts a circular area of the inner surface 126 of the flexible membrane 122 while the other pressurizable chambers 132, 134 contact annular areas of the inner surface 126 of the flexible membrane 122. In other embodiments, different geometric arrangements of the pressurizable chambers relative to the flexible membrane 122 can be used. The polishing head 104 is coupled to a rotatable shaft 145. The polishing head 104 is rotatable by rotation of the rotatable shaft 145. A motor 144 rotates the polishing head 104 about a rotational axis relative to the polishing surface 110 of the polishing pad 106. A motor 146 moves the polishing head 104 laterally in a linear motion (X and/or Y direction) relative to the arm 148. The CMP system 100 also includes an actuator or motor 150 to move the polishing head 104 in the Z direction relative to the arm 148 and/or the polishing pad 106. The motors 144, 146, 150 position and/or move the polishing head 104 relative to the polishing surface 110 and provide a downward force to urge the substrate 108 against the polishing surface 110 of the polishing pad 106 during processing.

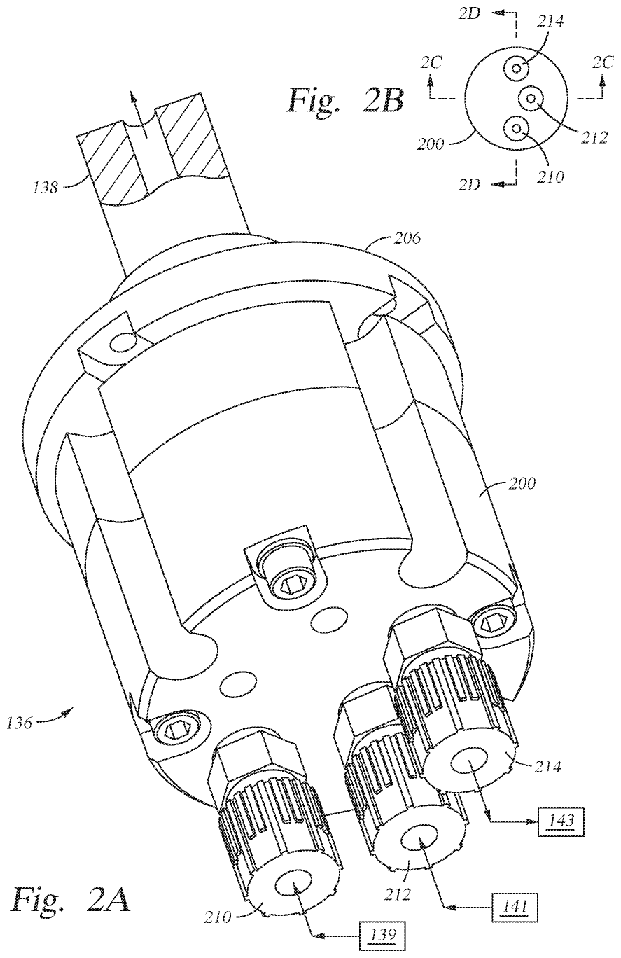

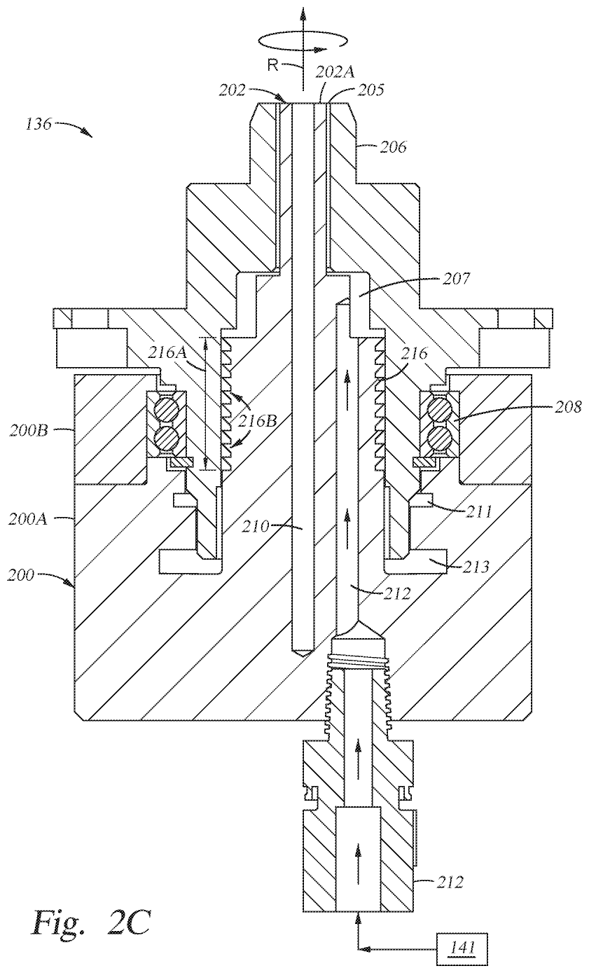

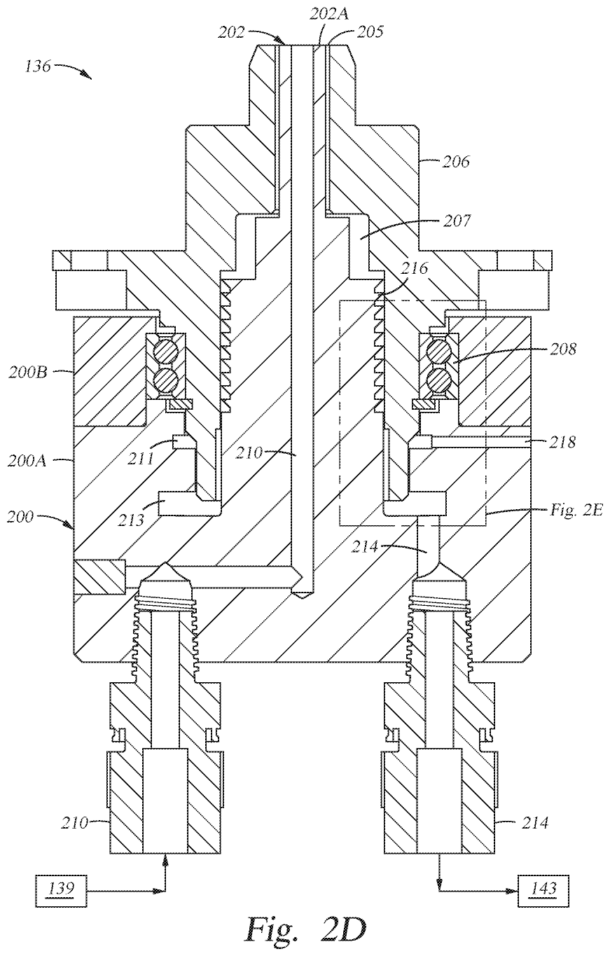

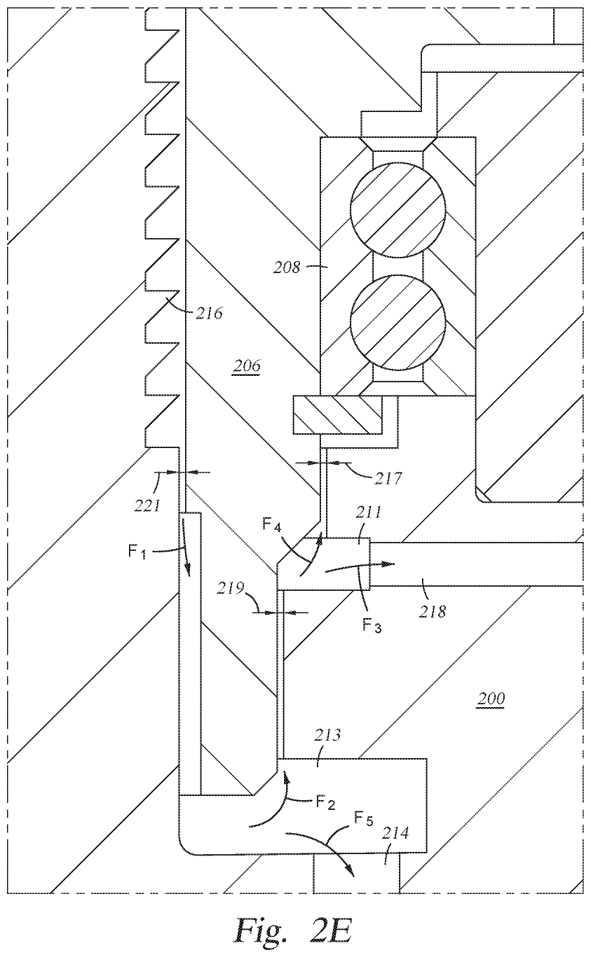

The CMP system 100 includes a rotary union 136 and a rotatable shaft 138 having a first end 140 and a second end 142. The rotary union 136 is coupled to the rotatable shaft 138 proximate the first end 140 of the rotatable shaft 138. The rotary union 136, as will be described in further detail in FIGS. 2A-2C, has stationary elements 200 and a rotary element 206. The rotary union 136 permits fluids to flow to the polishing surface 110 while the rotatable shaft 138 rotates. The platen 112 is rotatable by rotation of the rotatable shaft 138. The motor 114 is coupled to the rotatable shaft 138 proximate the second end 142.

The CMP system 100 further includes a first fluid source 139, a second fluid source 141, and a drain component 143. The first fluid source 139 carries a process fluid and flows through a first channel 210 (shown best in FIG. 2A) and through the platen 112 where it is delivered directly underneath of the substrate 108. The second fluid source 141 carries a supporting media and flows through a second channel 212 (shown best in FIG. 2A) and through the platen 112 where it is delivered directly underneath of the substrate 108. A drain component 143 acts as storage for backflow that flows through the drain port 214 (shown best in FIG. 2A).

FIG. 2A is a perspective view, FIG. 2B a bottom view, FIG. 2C-2D sectional views formed using the section lines illustrated in FIG. 2B, and FIG. 2E a close up sectional view of the rotary union 136 illustrated in FIG. 1. The rotary union 136 includes the stationary elements 200 that include a nozzle region 202 (as shown best in FIG. 2C). The stationary elements 200 are rotationally coupled to the rotary element 206 of the rotary union 136 (FIGS. 2A-2D). In some embodiments, the stationary elements 200 may include a plurality of hardware components, such as base 200A and bearing housing 200B. However, in other embodiments, the stationary element 200 can include a single unitary component. The stationary elements 200 can be made of a plastic material (e.g., PEEK, PPS, polypropylene, PTFE, PVDF), a ceramic material, a metal material, such as stainless steel or aluminum, or combination thereof, however other materials can also be used. The stationary elements 200 are rotationally coupled to the rotary element 206 by a bearing 208. The bearing 208 is a device that is able to support and allow rotational motion between components, and may include ball bearings, roller bearings, plain bearing or journal bearing. The rotary element 206 can be made of a metal material, a ceramic material or a plastic material, such as PEEK, polypropylene, PVDF, PTFE or PPS, however other materials can also be used.

The nozzle region 202 includes one or more channels, such as the first channel 210 illustrated in FIGS. 2C-2D, that are each separately coupled to a fluid delivery source (e.g., fluid sources 139 and 141). The fluid delivery sources are configured to deliver a processing fluid (e.g., slurry, cleaning fluid, DI water, etc.) out of the nozzle region 202 of the rotary union 136 and to the polishing surface 110 of the platen 112. While FIGS. 2C-2D illustrate a single fluid channel formed within the nozzle region 202 of the stationary element 200, this configuration is not intended to be limiting as to the scope of the invention provided herein.

The stationary elements 200 also include a plurality of supporting fluid channels, including the second channel 212 and the drain port 214. The supporting fluid channels are generally used to enable the rotary union 136 to properly function as a device that is able to transfer the processing fluid from a stationary component to a rotating component using the first channel 210 during normal operation and/or provide passages that allow any unwanted fluids to be directed from the rotary union to a waste collection assembly.

Although three channels are shown in this embodiment, more than three channels can also be used. In this configuration, the first channel 210 delivers a process media such as processing fluid (e.g., slurry or chemistry) at a first pressure from a first fluid source 139 (FIG. 2D) into the first channel 210 and out of the nozzle region 202 and into a port formed in the rotatable shaft 138 or tube (not shown) in the rotatable shaft 138 that leads to the surface 110 of the platen 112.

The second channel 212 delivers a fluid (e.g., supporting media and/or cleaning media) at a second pressure to a plenum 207 formed within the rotary union 136. The supporting media can include a gas (e.g., CDA, N2) or liquid (e.g., DI water). The supporting media helps prevent or control processing fluid leakage within and/or from the rotary union 136. In some configurations, application of the supporting media inhibits the process media from entering a gap 205 (FIG. 2C) between the nozzle region 202 of the stationary elements 200 and the rotary element 206. In some embodiments, the gap 205 can be between about 3 micrometers (μm) and about 1 millimeters (mm) wide. In other embodiments, the gap 205 can be between 100 μm and about 200 μm wide.

By regulating the supporting media pressure within the plenum 207, and thus the gap 205 formed between the nozzle region 202 and the adjacent portions of the rotary element 206, a non-contact seal is created within the gap 205. In some configurations, the pressure of the supporting media within the plenum 207 is maintained by the second fluid source 141 at a pressure greater than or equal to the pressure of a fluid (e.g., processing fluid or air) positioned at the entrance of the gap 205 positioned adjacent to the nozzle surface 202A positioned at the end of the nozzle region 202. The controlled pressure of the supporting media in the plenum 207 is thus used to minimize the amount of or prevent a processing fluid from flowing through the gap 205 from the nozzle surface 202A and into the plenum 207. In some configurations, the flow rate or leak rate of the processing fluid is controlled by the pressure difference between the supporting media and the processing fluid. For example, if the supporting media pressure is in equilibrium with the processing fluid pressure, neither (1) the supporting media leaks into the process area adjacent to the nozzle surface 202A or (2) the processing fluid backflows into the rotary union 136. When the processing fluid is delivered through the first channel 210, the process media pressure will tend to cause the processing fluid to backflow into the rotary union 136. However, when at least an equal amount of supporting media pressure is applied within the plenum 207, the process media backflow is stopped and does not flow into a seal located between the plenum 207 and a gap 221. The seal can be positioned within a length 216A (FIG. 2C). While a labyrinth seal 216 is shown in FIGS. 2A-2C, the seal can be a contact seal, a gap, or any other known operable seals in the art. A primary function of the labyrinth seal 216 is to maintain necessary pressure within the plenum 207 and to prevent or control leakage of the supporting media into the drain port 214.

However, if the any processing fluid is able to make its way into the plenum 207, the seal (e.g., labyrinth seal 216 structure) is used to prevent or inhibit the flow of fluid out of the rotary union 136 and acts to provide a controlled leak of the fluid into the drain port 214. As illustrated in FIG. 2E, the labyrinth seal 216 inhibits flow of any fluid, as indicated by flow F1, by use of a plurality of regularly spaced protruding features 216B, resulting in a long and difficult path for the processing fluid to travel from the plenum 207 to a gap 221. The labyrinth seal 216 has a length 216A, which is measured in the rotation axis R direction (FIG. 2C). In one configuration, the regularly spaced features 216B are formed in a “tongue and groove” shape. In one example, as shown in FIG. 2E, each of the features 216B of the “tongue and groove” shape include a triangular cross-sectional shape with the tip of the triangle forming a gap (e.g., gap 221) with the wall of the rotary element 206. Although much of the processing fluid is inhibited by the labyrinth seal 216, some processing fluid may make its way into the gap 221 which further leads into a plenum 213, as shown by flow F2 in FIG. 2E. The gap 221 is located between the stationary elements 200 and the rotary element 206, and is necessary to allow the rotary union 136 to rotate.

If any process media does leak into the plenum 213, configuration of the rotary union will cause the majority of the fluid to flow out of a drain port 214 and into the drain component 143. Due to a restriction created by gap 219 (FIG. 2E) formed between the stationary elements 200 and the rotary element 206, the majority of the processing fluid will flow into the drain port 214 that has a lower fluid restriction. The gap 219 can be any type of a labyrinth or contact seal as well. The fluid flowing out of the drain component 143 exits the rotary union 136, which is described further below. The drain port 214 acts as a drain that is able to collect portions of the processing fluid that has migrated from the nozzle region 202 through the plenum 207 and to the plenum 213 and out to the drain component 143 as shown by flow F5 (FIG. 2D). In some embodiments, the drain port 214 between about 2 mm and about 12 mm in diameter, however the drain port 214 is not limited to these diameters and can be any operable size.

However, some excess processing fluid may make its way into a gap 219 that leads into an additional plenum 211 (as shown best in FIG. 2E). The gap 219 is also located between the stationary elements 200 and the rotary element 206, and is necessary for the rotary union 136 to rotate. The processing fluid that flows into the additional plenum 211 is designed to flow out of a drain port 218 as shown by flow F3 such that it does not damage any parts of the rotary union 136, such as the bearing 208. Due to a restriction created by gap 217 (FIG. 2E) formed between the stationary elements 200 and the rotary element 206, the configuration of the rotary union tends to cause any remaining processing fluid to flow out of the drain port 218. The gap 217 can be any type of a labyrinth seal or contact seal as well. Thus, process media will generally not flow into the gap 217 as indicated by flow F4 and damage any parts of the rotary union 136, such as the bearing 208. The gap 217, however, is necessary for the rotary union 136 to rotate. In some embodiments, the drain port 218 between about 1 mm and about 12 mm in diameter, however the drain port 218 is not limited to these diameters can be any operable size. The drain port 218 can be used as an additional feature and does not need to operate continuously.

By adjusting the amount of fluid backflow into the rotary union 136 by creating a pressure difference between the supporting media and processing fluid and/or designing the length 216A of the labyrinth seal section (FIG. 2C), which is, for example, measured in the rotation axis direction, the size and length of the gaps 205, 217, 219 and 221 and sizes of the drain ports 214 and 218 the flow of any processing fluid within or out of the rotary union can be desirably controlled. In some embodiments, the stationary elements 200 and the rotary element 206 are formed from a plastic material. In some embodiments, the gap 205 can be between about 3 μm and about 1 mm. In some embodiments, the gaps 217, 219, and 221 can be between about 15 μm and about 35 μm, such as about 20 μm. However, the gaps 205, 217, 219, and 221 are not limited to these sizes and can be other operable sizes.

Use of the non-contact seal in conjunction with the supporting media provides many benefits. For example, the non-contact seal prevents or controls process media leakage in the rotary union 136 while enabling delivery of the process media through the platen 112 directly underneath of the substrate 108 without the risk of additional contamination of the process media, thus reducing the defect to the substrate 108. Delivery of the media directly underneath of the substrate 108 may increase the effectiveness of the process media, thus reducing its consumption. The ability to deliver the process media through the platen 112 allows for a more compact design of the process module. Additionally, the non-contact seal precludes particle generation due to seal wear, caused for example in face seals, and does not leech out any additional foreign elements. The supporting media can also be sued to clean the non-contact seal after use of the rotary union 136.

While the foregoing is directed to embodiments of the present disclosure, other and further embodiments of the disclosure may be devised without departing from the basic scope thereof, and the scope thereof is determined by the claims that follow.

We claim:

1. A rotary union, comprising:
a rotary element rotationally coupled to a stationary element by a bearing, wherein a surface of the rotary element is spaced a distance from a first surface of the stationary element to form a first gap, and
wherein the stationary element comprises:
a nozzle region that has an external surface disposed at one end of the nozzle region;
a first channel that extends through the nozzle region and the external surface of the nozzle region; and
a second channel that is in fluid communication with a first plenum, wherein the first plenum is defined by one or more surfaces of the stationary element and one or more surfaces of the rotary element, and the first plenum is in fluid communication with the space formed within the first gap.

2. The rotary union of claim 1, further comprising a seal positioned between the stationary element and the rotary element, wherein the first plenum is disposed between the space formed within the first gap and the seal.

3. The rotary union of claim 2, wherein the seal is a labyrinth seal that comprises a plurality of regularly spaced features.

4. The rotary union of claim 2, wherein the stationary element comprises a plastic material.

5. The rotary union of claim 1, wherein the first gap is between about 3 μm and about 1 mm wide.

6. The rotary union of claim 1, wherein the first gap is between about 100 μm and about 200 μm wide.

7. A method for transferring one or more fluids between components of a rotary union, comprising:
delivering a process media from a first fluid source into a first channel at a first pressure, wherein the first channel extends into a stationary element of the rotary union, and the rotary union further comprises a first gap that is formed between the stationary element and a rotary element that is rotationally coupled to the stationary element; and
delivering a supporting media from a second fluid source into a second channel at a second pressure, wherein the second channel extends into a plenum that is defined by one or more surfaces of the stationary element and one or more surfaces of the rotary element,
wherein the plenum is fluidly coupled to the first gap at one end, and
wherein the application of the supporting media inhibits the process media from entering the first gap.

8. The method of claim 7, wherein the first pressure and the second pressure are at equilibrium.

9. The method of claim 7, wherein the first pressure is higher than the second pressure.

10. The method of claim 7, wherein the first pressure is lower than the second pressure.

11. The method of claim 7, wherein the supporting media is a gas.

12. The method of claim 7, wherein the supporting media is a liquid media.

13. A system for transferring one or more fluids between components that are configured to rotate relative to each other, comprising:
a rotary union comprising:
a rotary element rotationally coupled to a stationary element by a bearing, wherein a surface of the rotary element is spaced a distance from a first surface of the stationary element to form a first gap;
wherein the stationary element comprises:
a nozzle region that has an external surface disposed at one end of the nozzle region;
a first channel that extends from a first fluid source external of the rotary union through the nozzle region and the external surface of the nozzle region; and
a second channel that extends from a second fluid source external of the rotary union, wherein the second channel is in fluid communication with a first plenum, wherein the first plenum is defined by one or more surfaces of the stationary element and one or more surfaces of the rotary element, and the first plenum is in fluid communication with the space formed within the first gap; wherein
the first fluid source is configured to deliver a process media at a first pressure;
the second fluid source configured to deliver a supporting media at a second pressure; and
the delivery of the supporting media inhibits the process media from entering the first gap.

14. The system of claim 13, further comprising a seal positioned between the stationary element and the rotary element, wherein the first plenum is disposed between the space formed within the first gap and the seal.

15. The system of claim 14, wherein the seal is a labyrinth seal.

16. The system of claim 13, wherein the first pressure and the second pressure are at equilibrium.

17. The system of claim 13, wherein the first pressure is higher than the second pressure.

18. The system of claim 13, wherein the first pressure is lower than the second pressure.

19. The system of claim 13, wherein the supporting media is a gas.

20. The system of claim 13, wherein the supporting media is a liquid media.
